(19) United States
(12) Patent Application Publication
(10) Pub. No.: US 2024/0219920 A1
(43) Pub. Date: Jul. 4, 2024

(54) SYSTEM AND METHOD FOR GENERATING THREE-DIMENSIONAL SPATIAL RADIO-WAVE MAP BY USING DRONE

(71) Applicant: ESSETEL. CO.,LTD, Daejeon (KR)

(72) Inventors: Joong Hee RYU, Paju-si (KR); Sung Eun JIN, Seogwipo-si (KR); Young Il KIM, Sejong-si (KR)

(21) Appl. No.: 18/570,264

(22) PCT Filed: Oct. 18, 2022
(86) PCT No.: PCT/KR2022/015821

§ 371 Date: Dec. 14, 2023

(30) Foreign Application Priority Data
Oct. 18, 2021 (KR) 10-2021-0138210
Oct. 11, 2022 (KR) 10-2022-0129460

(51) Int. Cl. G05D 1/246; G01S 13/89; G05D 105/80; G05D 107/10; G05D 109/20; G05D 111/30

(52) U.S. Cl. CPC G05D 1/246; G01S 13/89; G05D 2105/87; G05D 2107/10; G05D 2109/20; G05D 2111/30

(57) ABSTRACT

A method of operating a user terminal operating by at least one processor, wherein a bus information providing app executed according to a user input displays an information registration menu screen.

When an information registration signal is input, it is confirmed whether the information registration menu screen includes a bus stop surrounding image and additional information about the bus stop surrounding image, and bus stop surrounding information including the input bus stop surrounding image, the additional information, and location information of the user terminal is transmitted to a bus information system.

### TECHNICAL FIELD

The present invention relates to a system and method for generating a three-dimensional (3D) spatial radio wave map using a drone to recognize a radio wave environment in a 3D space such as skyscrapers and high-rise apartments.

### BACKGROUND ART

In modern times, downtown spaces densely populated with skyscrapers and high-rise apartments are increasing, and metropolitanization is accelerating. Accordingly, telecommunication companies that provide communication services to users located in high-rise buildings, or national organizations that provide disaster information through a national disaster network, have been unable to recognize radio wave environments in high spaces.

Therefore, shadow areas or arbitrary frequency overlap may occur in high spaces, which causes a problem in that communication quality deteriorates. In addition, since telecommunication companies do not know radio wave environments in high spaces, it is difficult for telecommunication companies to plan base station cells.

### DISCLOSURE

### Technical Problem

The present invention attempts to provide a system and method for generating a three-dimensional (3D) spatial radio wave map using a drone capable of securing a smooth communication quality for communication networks and national disaster networks in the downtown area by measuring a radio wave environment of a high space above the ground to respond to new and reconstructed high-rise buildings and topographical changes.

### Technical Solution

A method of operating a radio wave map generation system operating by at least one processor, which is a feature of the present invention for achieving the technical problem of the present invention, includes receiving a radio wave measurement zone where a drone is to measure a radio wave intensity and reference point information, generating a control signal including a frequency band of a radio wave to be measured by the drone in a plurality of virtual sectors constituting the radio wave measurement zone, a radio wave measurement period, a flight speed of the drone, and the reference point information that the drone is initially to be located, transmitting the radio wave at a preset intensity in the frequency band, and by the drone that received the control signal, receiving radio wave measurement information obtained by measuring the radio wave intensity while flying the plurality of virtual sectors, and generating a 3D radio wave map based on the radio wave measurement information.

The generating of the control signal may include dividing the radio wave measurement zone into the plurality of virtual sectors, and giving virtual sector identification information for each virtual sector.

The radio wave measurement information may include virtual sector identification information including a point where a radio wave intensity is measured, location information of the point, the radio wave intensity measured at the point, and identification information of the drone.

The generating of the 3D radio wave map may include converting a radio wave reception intensity included in the radio wave measurement information into a quantization size, and selecting a color and saturation corresponding to the converted quantization size based on the number of radio wave intensity expression frequencies and a radio wave intensity level value and expressing the color and saturation on a 3D space map.

A method of operating a drone operating by at least one processor, which is another feature of the present invention for achieving the technical problem of the present invention, includes receiving a control signal including a radio wave measurement zone, virtual sector identification information of each of a plurality of virtual sectors constituting the radio wave measurement zone, a frequency band of a radio wave to be measured by a drone, a radio wave measurement period, a flight speed of the drone, and reference point information that the drone is initially to be located from a radio wave map generation system, flying to a reference point based on the reference point information and measuring a radio wave reception intensity of the radio wave transmitted in the frequency band according to the radio wave measurement period, transmitting radio wave measurement information including location information of the reference point at which the radio wave reception intensity is measured, and the radio wave intensity, virtual sector identification information of a location to the radio wave map generation system, and moving in a specific direction according to the flight speed from the reference point.

The transmitting to the radio wave map generation system may include obtaining the location information of the reference point at which the radio wave reception intensity is measured by using a GPS RTK.

The method may further include, after the moving in the specific direction, measuring a radio wave intensity of a radio wave received according to the radio wave measurement period at a point moved in the specific direction.

A radio wave map generation system linked with a drone, which is another feature of the present invention for achieving the technical problem of the present invention, includes
an interface transmitting a control signal so that the drone measures a radio wave reception intensity, and receiving radio wave measurement information transmitted from the drone, and a processor, wherein the processor generates the control signal, transmits a radio wave of a frequency band to a radio wave measurement zone, and generates a 3D radio wave map based on the radio wave measurement information.

The processor may divide the radio wave measurement zone into a plurality of virtual sectors and give virtual sector identification information to each virtual sector.

The processor may convert a radio wave reception intensity included in the radio wave measurement information into a quantization size, select a color and saturation corresponding to the converted quantization size based on the number of radio wave intensity expression frequencies and a radio wave intensity level value, express the color and saturation on a 3D space map, and produce the 3D radio wave map.

The control signal may include a frequency band of a radio wave to be measured by the drone in a plurality of virtual sectors constituting the radio wave measurement zone in which the drone is to measure a radio wave intensity, a radio wave measurement period, 3D spatial information about a space to be measured by the drone, a flight speed of the drone, and reference point information that the drone is initially to be located.

A drone linked with a radio wave map generation system, which is another feature of the present invention for achieving the technical problem of the present invention, includes an interface receiving a control signal including a radio wave measurement zone, virtual sector identification information of each of a plurality of virtual sectors constituting the radio wave measurement zone, a frequency band of a radio wave to be measured by the drone, a radio wave measurement period, a flight speed of the drone, and reference point information that the drone is initially to be located from a radio wave map generation system; and a processor, wherein the processor flies to a reference point based on the reference point information, measures an intensity of the radio wave transmitted in the frequency band according to the radio wave measurement period, and generates radio wave measurement information including location information of the reference point at which the radio wave intensity is measured, the radio wave intensity, and virtual sector identification information of a location.

The processor may obtain the location information of the reference point at which the radio wave intensity is measured by using a GPS RTK.

### Advantageous Effect

According to the present invention, the high-quality wireless communication network for densely populated areas and high-rise spaces may be secured, and the safety of the public may be secured by securing the disaster wireless network.

In addition, the radio wave shadow area due to buildings and topographical characteristics may be identified, and thus, the broadcasting network hearing loss area and the shadow area may be eliminated by optimizing the optimal installation locations of repeaters and transmitters.

### DESCRIPTION OF THE DRAWINGS

FIG. 1 is an exemplary diagram of an environment to which a three-dimensional (3D) spatial radio wave map generation system according to an embodiment of the present invention is applied.

FIG. 2 is a structural diagram of the 3D spatial radio wave map generation system according to an embodiment of the present invention.

FIG. 3 is a structural diagram of a drone according to an embodiment of the present invention.

FIG. 4 is a flowchart of a method of measuring a spatial radio wave according to an embodiment of the present invention.

FIG. 5 is an exemplary diagram of a virtual sector according to an embodiment of the present invention.

FIG. 6 is an exemplary diagram of a computing device according to an embodiment of the present invention.

### MODE FOR INVENTION

The present invention will be described more fully hereinafter with reference to the accompanying drawings, so that those skilled in the art to which the present invention pertains may easily implement the embodiment of the present invention. However, the present invention may be embodied in many different forms and is not limited to the embodiments set forth herein. In order to clearly describe the present invention, parts irrelevant to the description are omitted from the drawings, and the same reference numerals are denoted by similar components throughout the specification.

In addition, throughout the specification, when a portion “includes” a certain component, it means that the portion may further include other components without excluding other components unless otherwise stated.

Hereinafter, a system and method for generating a three-dimensional (3D) spatial radio wave map using a drone according to an embodiment of the present invention are described in detail with reference to the drawings.

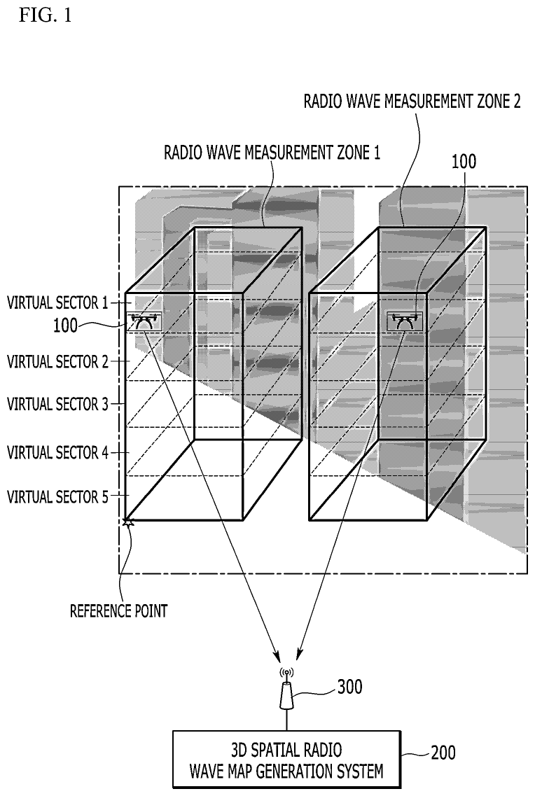

FIG. 1 is an exemplary diagram of an environment to which a 3D spatial radio wave map generation system 200 according to an embodiment of the present invention is applied.

As shown in FIG. 1, the 3D spatial radio wave map generation system 200 (hereinafter referred to as the ‘radio wave map generation system’ for convenience of explanation) is linked with a drone (or, also referred to as a ‘radio wave measurement means’) 100.

The drone 100 measures radio wave in a virtual sector formed in a space (hereinafter referred to as a ‘radio wave measurement zone’) allocated by the radio wave map generation system 200. Then, the drone 100 generates a measured radio wave intensity along with a radio wave measurement location as radio wave measurement information and transmits the radio wave measurement information to the radio wave map generation system 200. In an embodiment of the present invention, a case where a plurality of drones 100 simultaneously measure radio waves in virtual sectors within the respective radio wave measurement zones will be described as an example.

The radio wave map generation system 200 transmits the radio wave of which intensity to be measured by the drone 100 at 360 degrees through a base station 300. In addition, the radio wave map generation system 200 generates a 3D radio wave map based on the radio wave measurement information received from each drone 100.

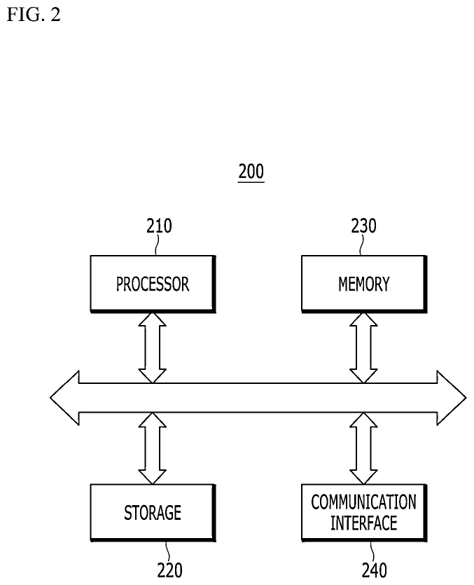

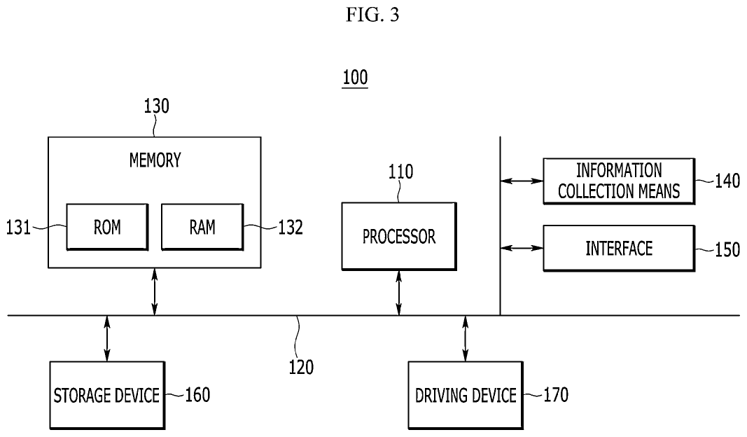

At this time, the structures of the radio wave map generation system 200 and the drone 100 will be described with reference to FIGS. 2 and 3.

FIG. 2 is a structural diagram of the radio wave map generation system 200 according to an embodiment of the present invention.

As shown in FIG. 2, the radio wave map generation system 200 operating by at least one processor executes a program including instructions described to execute an operation of the present invention.

Hardware of the radio wave map generation system 200 may include at least one processor 210, a memory 230, a storage 220, and a communication interface 240, which may be connected to each other via a bus. In addition, hardware such as an input device and an output device may be included. Various software, including an operating system capable of running programs, may be mounted on the radio wave map generation system 200.

The processor 210 is a device that controls an operation of the radio wave map generation system 200, and may be various types of processor 210 that processes instructions included in a program, for example, a Central Processing Unit (CPU), a Micro Processor Unit (MPU), a Micro Controller Unit (MCU), a Graphics Processing Unit (GPU), etc.

When the processor 210 receives information about a radio wave measurement target space, the processor 210 allocates a radio wave measurement zone in which each of the plurality of drones 100 is to measure radio wave. At this time, in the embodiment of the present invention, an example in which a 3D space of a rectangular parallelepiped of 100 m in width, 100 m in length, and 50 m in height is allocated as the radio wave measurement zone, and the radio wave measurement zone is set with respect to a reference point at an arbitrary location input by an administrator who manages the radio wave map generation system 200 will be explained.

In addition, the processor 210 divides the radio wave measurement zone into an arbitrary number of virtual sectors. For example, assuming that the drone 100 measures radio wave while rising vertically in the unit of 5 m, 10 virtual sectors are formed in the radio wave measurement zone with a height of 50 m.

The processor 210 transmits radio wave at a preset power. At this time, the processor 210 confirms a frequency band that is not used in an area transmitting radio wave, and inform each drone 100 of frequency band information of the radio wave so that each drone 100 may measure the intensity of the radio wave transmitted in the corresponding frequency band. When transmitting the radio wave, the processor 210 . . . 360 degrees.

In addition, the processor 210 generates a 3D radio wave map based on radio wave measurement information received from each drone 100. Here, the radio wave measurement information includes location information including altitude, latitude, and longitude at which each drone 100 measured the radio wave intensity, a radio wave reception intensity, and identification information of each drone 100.

The processor 210 converts the radio wave reception intensity into a quantization size based on actual radio wave intensity data measured through the drone 100. Then, the processor 210 renders the radio wave reception intensity converted into the quantization size on a map through a 3D radio map expression algorithm.

At this time, the processor 210 performs a function of a radio wave map production platform that selects a color and saturation corresponding to the radio wave reception intensity converted into the quantization size and expresses the color and the saturation on a 3D spatial map, based on a predetermined level value according to the number of radio wave intensity expression frequencies and the radio wave intensity transmitted by the radio wave map generation system 200.

The radio wave map generation system 200 is installed on the ground and transmits radio wave through one frequency channel. For example, when radio wave is transmitted at a frequency of 2.450 GHZ, the radio wave map generation system 200 measures a frequency environment in the sky divided into arbitrary virtual sectors through the drone 100 and renders the frequency environment as the radio wave reception intensity.

At this time, the radio wave map generation system 200 may transmit the radio wave by changing the frequency channel (e.g., 2.450 GHz→2.550 GHZ). In other words, the radio wave map generation system 200 may express a 2.450 GHz rendering image and a 2.550 GHz rendering image on a 3D space map at the same time, and selectively express one of the two images.

When expressing the 2.450 GHz rendering image on the 3D spatial map, the radio wave map generation system 200 may differently display the brightness according to the radio wave intensity. That is, the radio wave map generation system 200 may express an area with a strong radio wave intensity in a dark color and an area with a weak radio wave intensity in a dull color. At this time, the two frequency intensities of 2.450 GHz and 2.550 GHz are referred to as the number of radio wave intensity expression frequencies.

A method performed by the processor 210 of converting the radio wave reception intensity into the quantization size or a technology of rendering the quantization size on a map may be performed in various ways, and thus, the embodiment of the present invention is not limited to any one method.

The memory 230 loads the corresponding program such that the instructions described to execute the operation of the present invention are processed by the processor 210. The memory 230 may be, for example, read only memory (ROM), random access memory (RAM), etc. The storage 220 stores various data, program, etc. required to execute the operation of the present invention. The communication interface 240 may be a wired/wireless communication unit.

FIG. 3 is a structural diagram of the drone 100 according to an embodiment of the present invention.

As shown in FIG. 3, the drone 100 includes a processor 110, a memory 130, an information collection means 140, an interface 150, a storage device 160, and a driving device 170 that communicate with each other via a bus 120.

The processor 110 is a device that controls an operation of the drone 100, and may be various types of processor that processes instructions included in a program, for example, a Central Processing Unit (CPU), a Micro Processor Unit (MPU), a Micro Controller Unit (MCU), a Graphics Processing Unit (GPU), etc. Alternatively, the processor 110 may be a semiconductor device that executes instructions stored in the memory 130 or the storage device 160. The processor 310 may be configured to execute the functions and method described above.

The processor 110 measures the radio wave intensity received by the information collection means 140. To this end, the processor 110 performs a function of a spectrum analyzer. A method performed by the processor 110 of measuring the radio wave intensity is a known technology, and the embodiment of the present invention is not limited to any one method.

In addition, the processor 110 receives altitude, latitude, and longitude, which are location information about a measurement location where the radio wave intensity is measured, from the information collection means 140, and generates radio wave measurement information together with radio wave intensity information.

In addition, the processor 110 controls the driving device 170 so that the drone 100 measures the radio wave intensity while moving at a preset time interval or spatial interval in a radio wave measurement zone. In the embodiment of the present invention, an example in which the drone 100 measures the radio wave intensity while moving in a preset direction in a virtual sector at the preset time interval is explained.

The memory 130 may include various types of volatile or non-volatile storage media. For example, the memory 130 loads the corresponding program so that the instructions described to execute the operation of the present invention are processed by the processor 110, and may include read only memory (ROM) 131 and random access memory (RAM) 132.

In the embodiment of the present invention, the memory 130 may be located inside or outside the processor 110, and the memory 130 may be connected to the processor 110 through various known means.

The information collection means 140 corresponds to various sensors (e.g., a sensor, a GPS/RTK, etc.) through which the drone 100 that is driving collects information according to the operation of the present invention. In the embodiment of the present invention, an example in which a receiver receiving the radio wave and a GPS/RTK collecting location information obtained by measuring the radio wave intensity are used as the information collection means 140 is explained, but the present invention is not necessarily limited thereto.

The interface 150 is linked with the radio wave map generation system 200 and transmits the radio wave measurement information generated by the drone 100 to the radio wave map generation system 200. In addition, the interface 150 may receive a control signal transmitted from the radio wave map generation system 200 and transmit the control signal to the processor 110.

The storage device 160 may store reference point coordinate information of a radio wave measurement zone in which the drone 100 is to measure radio wave while flying.

The driving device 170 drives the drone 100 to fly in the allocated radio wave measurement zone according to the control of the processor 110.

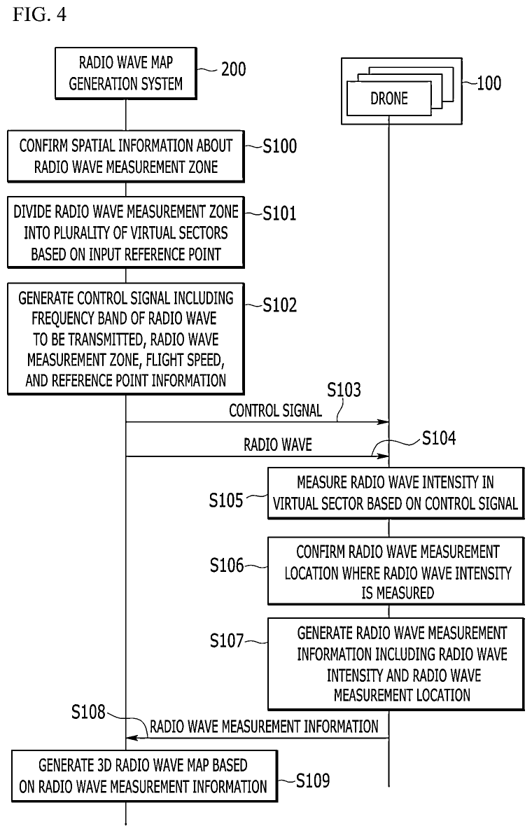

A method of measuring a spatial radio wave using the drone 100 in such an environment will be described with reference to FIG. 4. In the embodiment of the present invention, for convenience of explanation, one drone 100 is expressed as measuring the radio wave, but the same may be applied even when a plurality of drones measure radio waves.

FIG. 4 is a flowchart of a method of measuring spatial radio wave according to an embodiment of the present invention.

As shown in FIG. 4, the radio wave map generation system 200 confirms spatial information about a radio wave measurement zone input by an administrator (S100). Here, the spatial information refers to coordinate information of a virtual sector for radio wave measurement. That is, the spatial information includes drone control information along with start point information about longitude, latitude, and height, which are a 3D space that the drone 100 is to measure. The drone control information corresponds to mission flight information about flight speed information, flight path information, and flight time information of the drone 100.

In addition, the spatial information also includes reference point information input by the administrator. The reference point information may be coordinates and corresponds to location information that the drone 100 is to be located when first deployed in a radio wave measurement zone.

In the embodiment of the present invention, an example in which the administrator designates a radio wave measurement zone for each drone 100 to measure radio wave is explained, but the radio wave map generation system 200 may generate radio wave measurement zones by dividing a wide radio wave measurement target zone by the number of drones 100, and map the drone 100 to each of the generated radio wave measurement zones.

The radio wave map generation system 200 divides the radio wave measurement zone into a plurality of virtual sectors based on reference point information in the confirmed spatial information (S101). In other words, the radio wave map generation system 200 divides a 3D space corresponding to a rectangular parallelepiped or a regular hexahedron into virtual spaces (sectors) based on the reference point information, and there are various methods of dividing the 3D space into virtual spaces, and thus, the embodiment of the present invention is not limited to any one method.

The radio wave map generation system 200 generates a control signal including a frequency band of radio wave to be transmitted to each drone 100, a radio wave measurement period, information about the radio wave measurement zone, a flight speed, and the reference point information (S102), and transmits the control signal to the drone 100 (S103).

Here, the radio wave map generation system 200 increases the number of radio wave measurement points by lowering the flight speed of the drone 100 than a reference speed when the radio wave measurement zone is a downtown area where population and high-rise buildings are concentrated. In addition, the radio wave map generation system 200 reduces the number of radio wave measurement points by setting the flight speed of the drone 100 faster than the reference speed when the radio wave measurement zone is a sub-center area such as a factory area.

In addition, the radio wave map generation system 200 confirms in advance that the frequency band of radio wave to be transmitted to the drone 100 is a frequency band that is not used in the radio wave measurement zone, and uses the corresponding frequency band as a transmission frequency band for measuring radio wave intensity. To this end, it is assumed that the radio wave map generation system 200 knows information about a frequency band that is used or not used in the corresponding radio wave measurement zone.

The radio wave map generation system 200 transmits the control signal to the drone 100, and then transmits the radio wave of which intensity to be measured by the drone 100 (S104).

The drone 100 which has received the control signal transmitted from the radio wave map generation system 200 moves to a virtual sector including the reference point based on the control signal. Then, the drone 100 measures the radio wave intensity from the reference point (S105). The drone 100 may measure the radio wave intensity by using various methods, and thus, the embodiment of the present invention is not limited to any one method.

At the time of measuring the radio wave intensity, the drone 100 confirms a location where the radio wave intensity is measured (S106). To this end, the drone 100 confirms location information obtained by measuring the radio wave intensity by using a GPS RTK, which is a GPS measurement method, a GPS RTK method is a known technology, and a detailed description thereof is omitted in the embodiment of the present invention.

The drone 100 generates radio wave measurement information including the radio wave intensity measured in step S105 and the radio wave measurement location confirmed in step S106 (S107). The radio wave measurement information may include identification information of the drone 100 and virtual sector identification information assigned to each virtual sector.

The drone 100 transmits the radio wave measurement information generated in step S107 to the radio wave map generation system 200 (S108). In the embodiment of the present invention, an example in which the drone 100 generates the radio wave measurement information whenever measuring the radio wave intensity and transmits the radio wave measurement information to the radio wave map generation system 200 is explained, but the drone 100 may also generate the radio wave measurement information at a preset period and transmit the radio wave measurement information to the radio wave map generation system 200.

The radio wave map generation system 200 generates a 3D radio wave map based on the radio wave measurement information received in step S108 (S109).

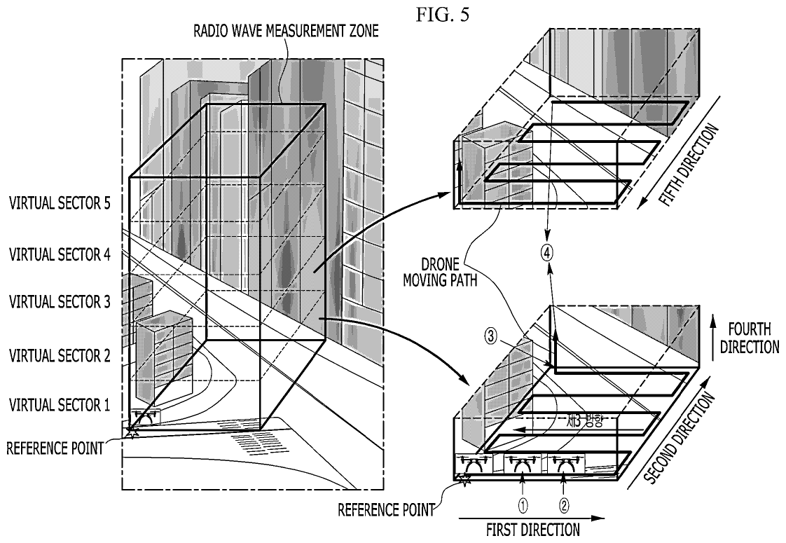

In the above-described procedure, an example of the virtual sector divided by the radio wave map generation system 200 will be described with reference to FIG. 5.

FIG. 5 is an exemplary diagram of a virtual sector according to an embodiment of the present invention.

As shown in FIG. 5, it is assumed that a radio wave measurement zone and a reference point are assigned to an arbitrary drone 100. Then, the drone 100 moves to the reference point according to the control of the radio wave map generation system 200 and measures a radio wave intensity at a period included in a control signal. At this time, the radio wave measurement zone is divided into a plurality of virtual sectors, and virtual sector identification information is given to each virtual sector.

Accordingly, the drone 100 moves to a virtual sector 1 including the reference point and measures a radio wave from the reference point. Then, the drone 100 transmits radio wave measurement information, including a location and radio wave intensity of the reference point, identification information of virtual sector 1, and identification information of the drone 100, to the radio wave map generation system 200.

After measuring the radio wave intensity at the reference point, the drone 100 moves in a first direction at a flight speed included in the control signal. In the embodiment of the present invention, a direction in which the drone 100 moves from left to right with respect to the reference point is expressed as the first direction, but the drone 100 may also move from left to right with respect to the reference point.

The drone 100 measures a radio wave intensity at a first point \textcircled{1} moving at the flight speed. In addition, the drone 100 transmits the radio wave measurement information, including a location of the first point \textcircled{1}, the radio wave intensity measured at the first point \textcircled{1}, the identification information of the drone 100, and the identification information of the virtual sector 1, to the radio wave map generation system 200.

In such a way, the drone 100 moves to a second point \textcircled{2} to measure a radio wave intensity, measures a radio wave intensity at a last location \textcircled{3} of the virtual sector, and then moves in a fourth direction to move a first location \textcircled{4} of a virtual sector 2. Then, the drone 100 measures radio wave intensity at a preset period within the virtual sector while moving in first, fifth, and third directions.

In the embodiment of the present invention, an example in which the drone 100 measures the radio wave intensity by moving in a zigzag manner in the virtual sector is explained, but the present invention is not necessarily limited thereto.

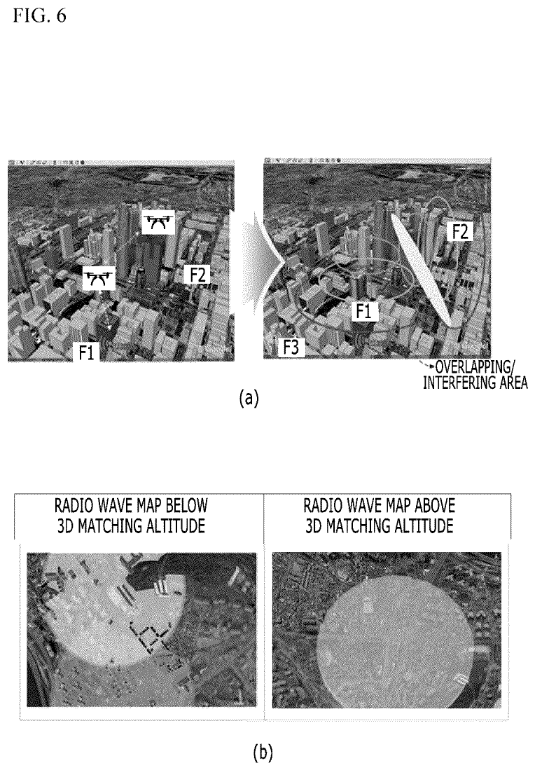

An example of a 3D radio wave map generated by the radio wave map generation system 200 using the radio wave measurement information provided by the drone 100 by measuring the radio wave intensity by using the above-described method will be described with reference to FIG. 6.

FIG. 6 is an exemplary diagram of a 3D radio wave map according to an embodiment of the present invention.

FIG. 6(a) is an exemplary diagram of an environment in which the drone 100 has measured a radio wave intensity, and FIG. 6(b) is an exemplary diagram of the 3D radio wave map generated by the radio wave map generation system 200 based on the radio wave intensity.

The 3D radio wave map may be divided into a radio wave map below a 3D matching altitude (hereinafter referred to as a ‘first radio wave map’) and a radio wave map above the 3D matching altitude (hereinafter referred to as a ‘second radio wave map’). The first radio wave map is a rendering algorithm based on color and saturation according to the number of measurement frequencies and radio wave intensity level, and expresses the radio wave intensity of the corresponding space in detail. In addition, the second radio wave map is a rendering algorithm based on color and saturation according to the radio wave intensity level for each expression frequency and roughly expresses the radio wave intensity.

As shown in FIG. 6, the radio wave map generation system 200 expresses the radio wave intensity in various ways according to the radio wave intensity at each location where the radio wave intensity is measured, based on radio wave measurement information transmitted from a plurality of drones 100. In the embodiment of the present invention, the radio wave intensity is indicated by color, but the present invention is not necessarily limited thereto.

In addition, the radio wave map generation system 200 displays an overlapping area if there is an area where the plurality of drones 100 overlap and measure the radio wave intensity. There are various methods performed by the radio wave map generation system 200 of determining an area where the same frequency overlaps or an area where a signal of the corresponding measurement frequency is interfered by adjacent frequencies, and thus, the embodiment of the present invention is limited to any one method.

Although the embodiments of the present invention have been described in detail above, the scope of the present invention is not limited thereto, and various modifications and improvements made by those of ordinary skill in the field to which the present invention pertains also belong to the scope of the present invention.

1. A method of operating a radio wave map generation system operating by at least one processor, the method comprising:
receiving a radio wave measurement zone where a drone is to measure a radio wave intensity and reference point information;
generating a control signal including a frequency band of a radio wave to be measured by the drone in a plurality of virtual sectors constituting the radio wave measurement zone, a radio wave measurement period, a flight speed of the drone, and the reference point information that the drone is initially to be located;
transmitting the radio wave at a preset intensity in the frequency band; and
by the drone that received the control signal, receiving radio wave measurement information obtained by measuring the radio wave intensity while flying the plurality of virtual sectors, and generating a three-dimensional (3D) radio wave map based on the radio wave measurement information.

2. The method of claim 1, wherein:
the generating of the control signal includes
dividing the radio wave measurement zone into the plurality of virtual sectors; and
giving virtual sector identification information for each virtual sector.

3. The method of claim 2, wherein:
the radio wave measurement information includes virtual sector identification information including a point where a radio wave intensity is measured, location information of the point, the radio wave intensity measured at the point, and identification information of the drone.

4. The method of claim 1, wherein:
the generating of the 3D radio wave map includes
converting a radio wave reception intensity included in the radio wave measurement information into a quantization size; and
selecting a color and saturation corresponding to the converted quantization size based on the number of radio wave intensity expression frequencies and a radio wave intensity level value and expressing the color and saturation on a 3D space map.

5. A method of operating a drone operating by at least one processor, the method comprising:
receiving a control signal including a radio wave measurement zone, virtual sector identification information of each of a plurality of virtual sectors constituting the radio wave measurement zone, a frequency band of a radio wave to be measured by a drone, a radio wave measurement period, a flight speed of the drone, and reference point information that the drone is initially to be located from a radio wave map generation system;
flying to a reference point based on the reference point information and measuring a radio wave reception intensity of the radio wave transmitted in the frequency band according to the radio wave measurement period;
transmitting radio wave measurement information including location information of the reference point at which the radio wave reception intensity is measured, and the radio wave intensity, virtual sector identification information of a location to the radio wave map generation system; and
moving in a specific direction according to the flight speed from the reference point.

6. The method of claim 5, wherein:
the transmitting to the radio wave map generation system includes
obtaining the location information of the reference point at which the radio wave reception intensity is measured by using a GPS RTK.

7. The method of claim 5, further comprising:
after the moving in the specific direction,
measuring a radio wave intensity of a radio wave received according to the radio wave measurement period at a point moved in the specific direction.

8. A radio wave map generation system linked with a drone comprising:
an interface transmitting a control signal so that the drone measures a radio wave reception intensity, and receiving radio wave measurement information transmitted from the drone; and
a processor,
wherein the processor
generates the control signal, transmits a radio wave of a frequency band to a radio wave measurement zone, and generates a 3D radio wave map based on the radio wave measurement information.

9. The radio wave map generation system of claim 8, wherein:
the processor
divides the radio wave measurement zone into a plurality of virtual sectors and gives virtual sector identification information to each virtual sector.

10. The radio wave map generation system of claim 9, wherein:
the processor
converts a radio wave reception intensity included in the radio wave measurement information into a quantization size, selects a color and saturation corresponding to the converted quantization size based on the number of radio wave intensity expression frequencies and a radio wave intensity level value, expresses the color and saturation on a 3D space map, and produces the 3D radio wave map.

11. The radio wave map generation system of claim 8, wherein:
the control signal includes a frequency band of a radio wave to be measured by the drone in a plurality of virtual sectors constituting the radio wave measurement zone in which the drone is to measure a radio wave intensity, a radio wave measurement period, 3D spatial information about a space to be measured by the drone, a flight speed of the drone, and reference point information that the drone is initially to be located.

12. A drone linked with a radio wave map generation system comprising:
an interface receiving a control signal including a radio wave measurement zone, virtual sector identification information of each of a plurality of virtual sectors constituting the radio wave measurement zone, a frequency band of a radio wave to be measured by the drone, a radio wave measurement period, a flight speed of the drone, and reference point information that the drone is initially to be located from a radio wave map generation system; and
a processor,
wherein the processor
flies to a reference point based on the reference point information, measures an intensity of the radio wave transmitted in the frequency band according to the radio wave measurement period, and generates radio wave measurement information including location information of the reference point at which the radio wave intensity is measured, the radio wave intensity, and virtual sector identification information of a location.

13. The drone of claim 12, wherein:
the processor
obtains the location information of the reference point at which the radio wave intensity is measured by using a GPS RTK.
